(19) United States
(12) Patent Application Publication
(10) Pub. No.: US 2002/0115303 A1
(43) Pub. Date: Aug. 22, 2002

(54) Semiconductor device and method of producing the same

(75) Inventors: Hiroshi Ohta, Kawasaki (JP); Shinichiro Takatani, Koganei (JP); Toshimi Yokoyama, Chofu (JP); Takeshi Kikawa, Kodaira (JP)

Correspondence Address: Stanley P. Fisher, Reed Smith Hazel & Thomas LLP, Suite 1400, 3110 Fairview Park Drive, Falls Church, VA, 22042-4503, US

(73) Assignee: Hitachi, Ltd.

(21) Appl. No.: 10/013,517

(22) Filed: Dec. 13, 2001

(30) Foreign Application Priority Data
Feb. 21, 2001 (JP) 2001-044425

(51) Int. Cl. H01L 21/31

(52) U.S. Cl. 438/765; 438/767

(57) ABSTRACT

A semiconductor device has a strongly bonding structure for improving bond strength between the semiconductor and the insulating layer even if the insulating layer is formed by a traditional method which causes slight damage to the semiconductor. The strongly bonding structure includes an oxide layer 12 (containing a constituent element of the semiconductor), an oxide bonding layer, a bond-creating layer (which may disappear from the finished product), and an insulating layer, which are sequentially formed one over the other. The oxide layer may be either one which occurs naturally or one which is formed artificially. The oxide bonding layer is formed by reaction between oxygen in the oxide layer and a constituent element in the bond-creating layer. The bond-creating layer contains an element that oxidizes and an element that reacts with a constituent element of the insulating layer.

### BACKGROUND OF THE INVENTION

1. Field of the Invention

The present invention relates to a semiconductor device having an insulating layer, such as a surface protective layer. The present invention relates also to a method of producing the same.

2. Description of the Related Arts

Surface protection is essential for semiconductor devices such as field effect transistor in order to prevent their surface from being oxidized or contaminated, to prevent them from being damaged in their manufacturing steps, and to reduce their leakage current. For this purpose, an insulating film (such as SiO₂ film and SiN film), which functions as a protective film, is formed directly on the surface of semiconductor devices by thermal CVD (chemical vapor deposition), as described in the Japanese Journal of Applied Physics, vol. 37, p. 1374.

The insulating film for the edge protection of laser diodes and photodiodes are required to maintain an adequately controlled reflectivity (thickness and refractive index) for their optimal light-receiving or light-emitting efficiency. This object can be achieved by a SiO₂ film, a SiN film, a or Al₂O₃ film, which is formed by the sputtering processing described in Applied Physics Letters, vol. 34, p. 685.

The thermal CVD processing for forming an insulating film as a surface protective layer for field effect transistors offers the advantage of merely slightly damaging the active layer. However, it suffers the disadvantage of forming a film susceptible to peeling due to insufficient bonding to the semiconductor device.

The sputtering processing used for forming an insulating film as an edge protective film for laser diodes and photodiodes is effective in controlling reflectivity. However, it suffers the same disadvantage as the thermal CVD processing.

### OBJECT AND SUMMARY OF THE INVENTION

It is an object of the present invention to provide a strongly-bonded structure which ensures a strong bonding between the semiconductor and an insulating layer formed thereon by such selected methods as thermal CVD, photo-induced CVD, laser CVD, and ECR-sputtering, which merely slightly damage the semiconductor.

The strongly-bonded structure is completed by sequentially laminating on the semiconductor an oxide layer (containing one element constituting the semiconductor), an oxide bonding layer, a bond-creating layer, and an insulating layer. (There may be an instance where the bond-creating layer has disappeared in the finished semiconductor device.)

The oxide layer is formed either by natural oxidation or by artificial oxidation. The oxide bonding layer is formed by reactions between oxygen in the oxide layer and an element constituting the bond-creating layer. The bond-creating layer contains an element which oxidizes as well as an element which reacts with an element constituting the insulating layer. In the case where the bond-creating layer is a silicon layer and the insulating layer is a silicon nitride layer, silicon in the bond-creating layer oxidizes and reacts with nitrogen as a constituent of the insulating layer. The bond-creating layer disappears if the silicon therein is completely consumed to form the oxide bonding layer or the silicon therein is completely consumed to form the oxide bonding layer and to react with an element constituting the insulating layer. The present invention improves the bonding between the semiconductor and the insulating layer regardless of the method by which the insulating layer is formed. The present invention is effective even if the insulating layer is formed by plasma CVD which ensures the firm bonding at the cost of damaging the semiconductor.

Other and further objects, features and advantages of the invention will appear more fully from the following description.

### BRIEF DESCRIPTION OF THE DRAWINGS

The preferred embodiments of the present invention are illustrated in the accompanying drawings in which:

FIG. 1 is a se of sequential sectional views showing the formation of a metamorphic HEMT according to the present invention;

FIG. 2 is a set of sequential sectional views showing the formation of a pseudomorphic HEMT according to the present invention;

FIG. 3 is a set of sequential sectional view showing a the formation of heterojunction bipolar transistor according to the present invention;

FIGS. 4(a)-4(c) are sectional views showing the formation of a semiconductor laser according to the present invention, and FIG. 4(d) is a top view of the semiconductor laser;

FIGS. 5(a)-5(c) are sectional views showing the formation of another semiconductor laser according to the present invention, and FIG. 5(d) is another sectional view of said another semiconductor laser;

FIGS. 6(a)-6(c) are sectional views showing the formation of a photodiode according to the present invention, and FIG. 6(d) is another sectional view of the photodiode;

FIG. 7 is a sectional view of a monolithic microwave integrated circuit according to the present invention;

FIG. 8 is a circuit diagram showing the fundamental circuit of a high-frequency module according to the present invention;

FIG. 9 is a sectional view showing a packaged semiconductor laser of FIG. 4(d) or FIG. 5(d) according to the present invention;

FIG. 10 is a sectional view showing a packaged photodiode of FIG. 6(d) according to the present invention; and

FIG. 11 is a graph showing the relationship between the just-finished deposited thickness of the bond creating layer and the adhesive strength of the invention.

### DESCRIPTION OF THE PREFERRED EMBODIMENTS

### EXAMPLE 1

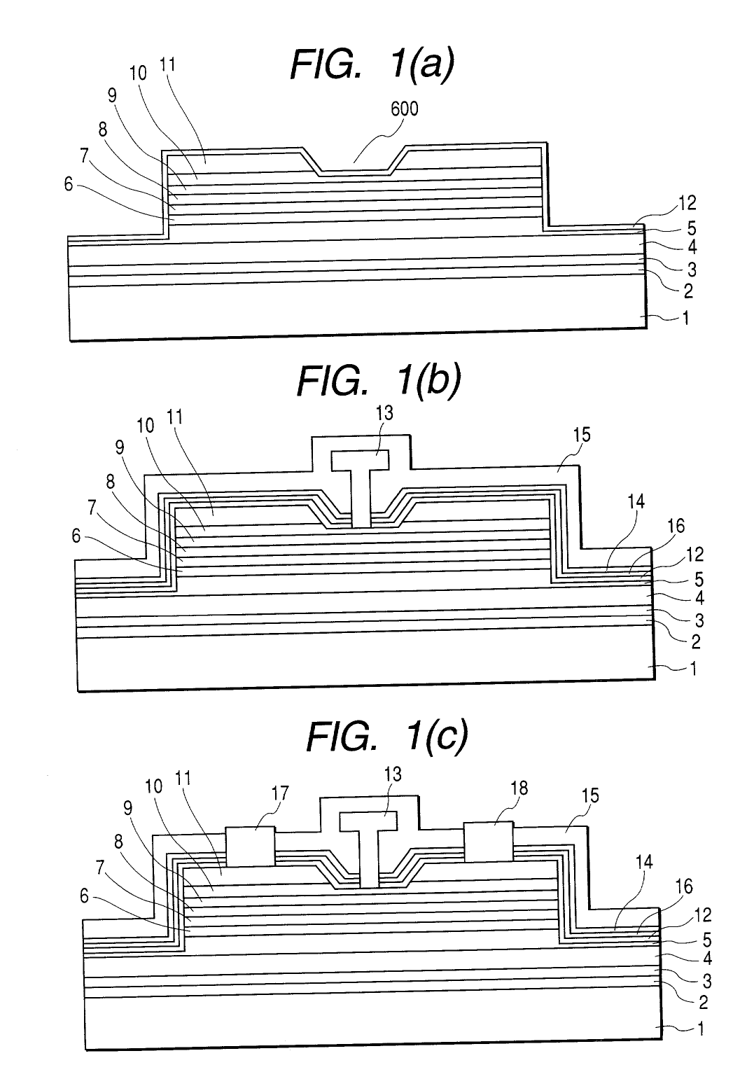

This example demonstrates the production of a metamorphic HEMT (high electron mobility transistor). As shown in FIG. 1, the production starts with sequential epitaxial growth of various layers (specified below) on a GaAs substrate 1.

undoped GaAs buffer layer (28 nm thick) 2

undoped AlAs buffer layer (20 nm thick) 3

undoped InAlAs step graded layer (600 nm thick) 4 (with InAs molar ratio changing from 0.15 to 0.45)

undoped In_{0.5}Al_{0.5}As barrier layer (200 nm thick) 5

undoped In_{0.5}Ga_{0.5}As channel layer (20 nm thick) 6

undoped In_{0.5}Al_{0.5}As layer (2 nm thick) 7

Si-doped n-In_{0.5}Al_{0.5}As carrier-supplying layer (12 nm thick) (5×10¹⁸ cm⁻³) 8

undoped In_{0.5}Al_{0.5}As layer (10 nm thick) 9

undoped InP layer (7 nm thick) 10

Si-doped n-In_{0.5}Ga_{0.5}As cap layer (120 nm thick) (5×10¹⁹ cm⁻³) 11

For mesa isolation, the epitaxially grown layers undergo etching down to the middle of the undoped In_{0.5}Al_{0.5}As barrier layer 5. Then the n-In_{0.5}Ga_{0.5}As cap layer 11 is partly etched so that the undoped InP layer 10 is exposed. (In this way, a gate recess 600 is formed.) In this stage, the semiconductor layers 5, 10, and 11 have an exposed top surface and the semiconductor layers 5 to 11 also have an exposed end surface. A native oxide film (1-5 nm thick) 12, which is composed of oxides, occurs on the exposed surface. (See FIG. 1(a)) The native oxide film 12 on the exposed surface of the undoped In_{0.5}Al_{0.5}As barrier layer 5 is composed of In₂O₃, Al₂O₃, and As₂O₃ which contain the constituent elements (In, Al, and As) of the barrier layer.

On the undoped InP layer 10 in the gate recess 600 is formed a T-shaped gate electrode 13 by the lift-off technique. On the entire surface are sequentially formed an Si bond-creating layer 14 (3 nm thick) and an SiN insulating layer 15 (150 nm thick), which functions as a surface protective layer, via ECR-sputtering (ECR=electron cyclotron resonance). In the course of these steps, an oxide bonding layer 16 occurs between the native oxide film 12 and the Si bond-creating layer 14. (See FIG. 1(b)) The oxide bonding layer 16 is an oxide composed of oxygen in the native oxide film 12 and silicon in the Si bond-creating layer 14. If the native oxide film 12 is formed on the exposed surface of the undoped In_{0.5}Al_{0.5}As barrier layer 5, the oxide has such bonds as In—O—Si, Al—O—Si, and As—O—Si which comprises oxygen originating from In₂O₃, Al₂O₃, and As₂O₃ therein and silicon originating from the Si bond-creating layer 14. The reaction between oxygen and silicon is induced by energy, which silicon possesses after excited, when the Si bond-creating layer 14 is formed.

The strongly bonding structure in this example consists of the native oxide film 12, the oxide bonding layer 16, the Si bond-creating layer 14, and the SiN insulating layer 15. The Si bond-creating layer 14 may disappear from the finished product. As mentioned, the oxide bonding layer 16 is formed by the mutual bonding of atoms of the native oxide film 12 and the Si bond-creating layer 14. Therefore, the native oxide film 12, the oxide bonding layer 16, and the Si bond-creating layer 14 firmly bond together. In addition, the native oxide film 12 and each semiconductor layer firmly bond together through bonding of their constituent atoms. The Si bond-creating layer 14 and the SiN insulating layer 15 firmly bond together since an Si layer and an SiN layer usually firmly bond together. Consequently, each neighboring semiconductor layer formed on the GaAs substrate firmly bonds to the SiN insulating layer 15. The oxide film on the surface of the semiconductor, which is necessary for forming the oxide bonding layer 16, is not limited to a native oxide film, but it may be an artificial one which is formed by oxygen plasma.

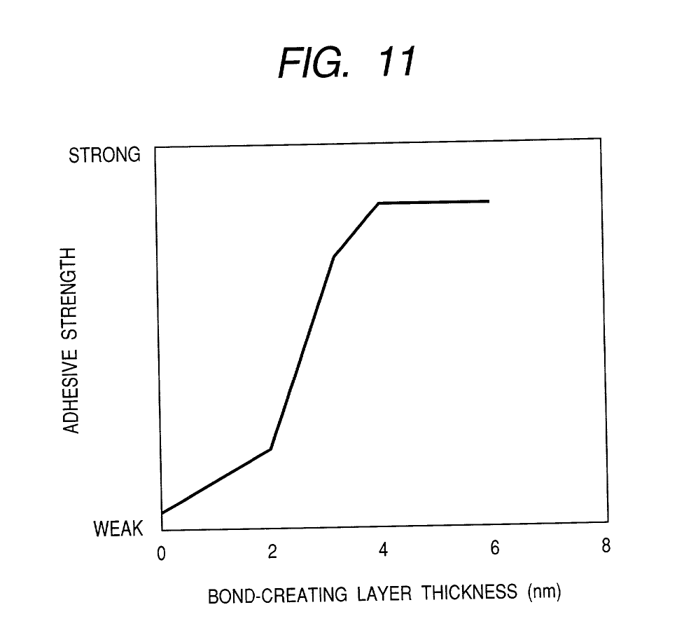

The just-finished deposited thickness of the bond creating layer 14 is preferably more than 3 nm as shown in FIG. 11. Above 3 nm, the adhesive strength become sufficient and almost saturated. And less than 2 nm, the adhesive strength is relatively poor. At the interface, atoms in the bond-creating layer 14 bond with oxygen atoms in the oxide layer 12 into the oxide bonding layer 16. So that the thickness of the oxide bonding layer 16 is more than the thickness of a single atomic layer, i.e. 0.6 nm.

After the whole bonding structure is completed, that final thickness the bond creating layer 14 may be reduced. The reduction depends on the condition of interface(or the semiconductor surface). In an extreme case, the bond creation layer is totally vanished.

Finally, on the n-In_{0.5}Ga_{0.5}As cap layer, a source electrode 17 and a drain electrode 18 are formed by the lift-off technique. (See FIG. 1(c))

The Japanese patent application No. 02-192127 by the Electronics and Telecommunications Research Institute discloses a three-layer structure without any bond creation layers. In the prior art reference, Si atoms may exist underneath the gate electrode or the lowest part of the gate electrode only if the Si atoms diffused or alloyed incidentally. If any Si atoms under a gate-electrode, the Schottky barrier height for the gate electrode will vary such that the characteristics of transistor vary uncontrollably. As the gate electrode metal is deposited selectively, the materials of the gate electrode further restrict the presence of any Si atoms since some materials could not form a gate-electrode on a Si layer. In contrast, in the invention, Si atoms does not exist under the gate electrode, but all over a surface or an interface to create a bonding force. In addition, the prior art reference does not teach a Si layer under an oxide layer (a SiO2 film) as the present invention.

The High Electron Mobility Transistor (“HEMT”) produced in this example is characterized in that the SiN insulating layer 15 is formed on the surface of the semiconductor layers 5, 10, and 11 and on the end surface of the semiconductor layers 5 to 11 such that the Si bond-creating layer 14 is inserted thereunder. Therefore, the SiN insulating layer 15 firmly bonds to the semiconductor layers even if it is formed by the ECR-sputtering technique.

This technique is applied not only to an InAlAs/InGaAs metamorphic HEMT on a GaAs substrate (as mentioned above) but also to an InAlAs/InGaAs HEMT on an InP substrate, an AlGaAs/InGaAs pseudomorphic HEMT on a GaAs substrate, as well as other FETs such as MESFETs and JFETs.

### EXAMPLE 2

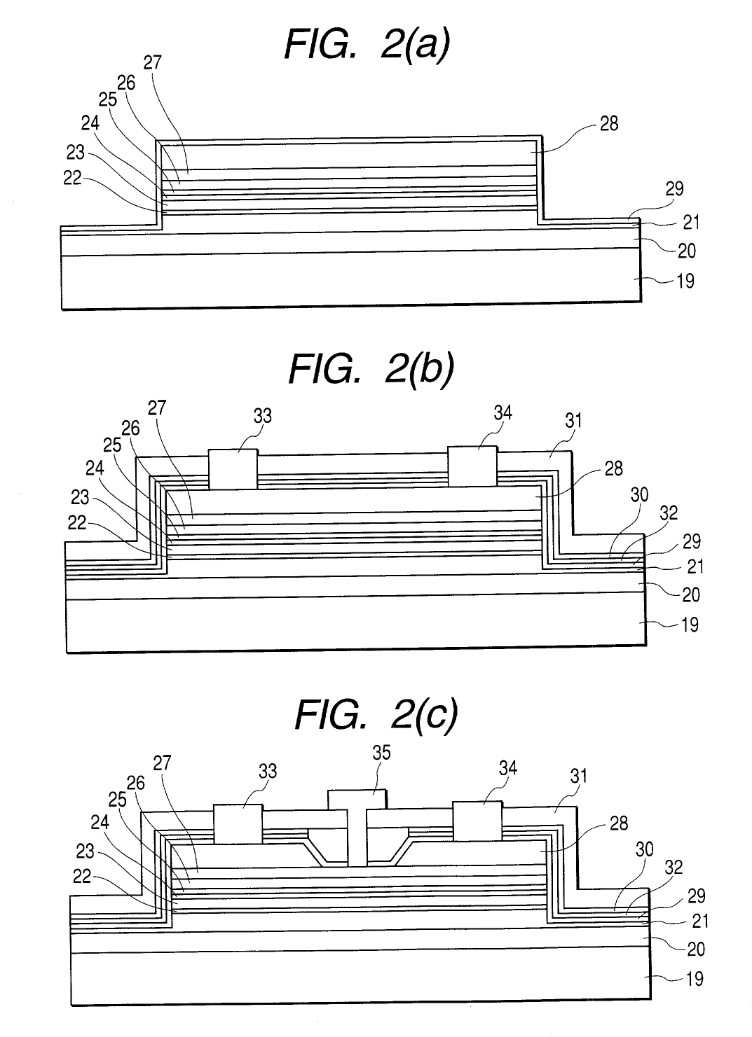

This example demonstrates the production of a pseudomorphic HEMT which is constructed such that there is an opening around the gate electrode. As shown in FIG. 2, the production starts with sequential epitaxial growth of various layers (specified below) on a GaAs substrate 19.

undoped GaAs buffer layer (100 nm thick) 20

undoped Al_{0.25}Ga_{0.75}As buffer layer (100 nm thick) 21

undoped GaAs layer (2 nm thick) 22

undoped In_{0.25}Ga_{0.75}As channel layer (8 nm thick) 23

undoped GaAs layer (2 nm thick) 24

undoped Al_{0.25}Ga_{0.75}As channel layer (2 nm thick) 25

Si-doped n-Al_{0.25}Ga_{0.75}As layer (12 nm thick)(4×10¹⁸ cm⁻³) 26

Si-doped n-Al_{0.25}Ga_{0.75}As layer (20 nm thick)(5×10¹⁶ cm⁻³) 27

Si-doped n-GaAs layer (180 nm thick) (5×10¹⁸ cm⁻³) 28

For mesa isolation, the epitaxially grown layers undergo etching down to the middle of the undoped Al_{0.25}Ga_{0.75}As layer 21. In this stage, the semiconductor layers 21 and 28 each has an exposed top surface and each of semiconductor layers 21 to 28 has an exposed end surface. A native oxide film (1-5 nm thick) 29 occurs on the exposed surface, which is composed of oxides as an constituent element. The native oxide film 29 is composed of In₂O₃, Ga₂O₃, As₂O₃, and Al₂O₃ which contain a respective constituent element (i.e., In, Ga, As, and Al) of the semiconductor layers. (See FIG. 2(a))

Then, an Si bond-creating layer 30 (3 nm thick) and an SiN insulating layer 31 (150 nm thick), which functions as a surface protective layer, are sequentially formed on the entire surface by ECR-sputtering. In the course of these steps, the oxide bonding layer 32 between the native oxide film 29 and the Si bond-creating layer 30 occurs by combination of oxygen (in the native oxide layer 29) and silicon (in the Si bond-creating layer 30). A source electrode 33 and a drain electrode 34 are formed on the n-GaAs cap layer 29 by the lift-off technique. (See FIG. 2(b))

Finally, an opening for the gate electrode is formed by etching the Si surface protective insulating layer 31, the Si bond-creating layer 30, and the oxide bonding layer 32. An opening around the gate electrode is formed by etching the native oxide film 29 and the n-GaAs cap layer 28 through the opening of the gate electrode. The gate electrode 35 is formed on the exposed n-Al_{0.25}Ga_{0.75}As layer 27 by a lift-off technique. In this way, the desired pseudomorphic HEMP is completed. (See FIG. 2(c))

The strongly bonding structure in this example consists of the native oxide film 29, the oxide bonding layer 32, the Si bond-creating layer 30, and the SiN insulating layer 31. The Si bond-creating layer 30 may disappear from the finished product. As in Example 1, the HEMT in this example is characterized in that the SiN insulating layer 31 is formed on the surface of the semiconductor layers 21 and 28 and on the respective end surface of each of the semiconductor layers 21 to 28 such that the Si bond-creating layer 30 is inserted thereunder. Therefore, the SiN insulating layer 31 firmly bonds to the semiconductor layers even if it is formed by the ECR-sputtering technique.

The technique in this example may be applied not only to the pseudomorphic HEMT mentioned above but also to other FETs.

### EXAMPLE 3

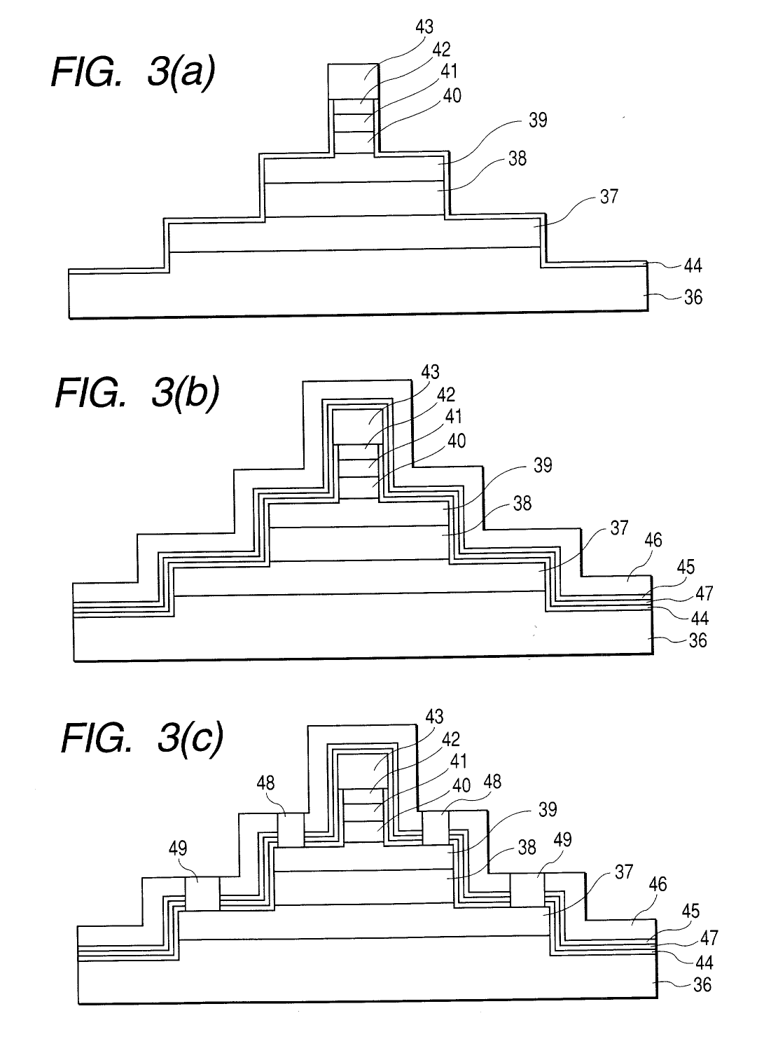

This example demonstrates the production of an InGaP/GaAs HBT (heterojunction bipolar transistors). As shown in FIG. 3, the production starts with sequential epitaxial growth of various layers (specified below) on a GaAs substrate 36.

Si-doped GaAs subcollector layer (700 nm thick) (5×10¹⁸ cm⁻³) 37

Si-doped GaAs collector layer (150 nm thick) (5×10¹⁸ cm⁻³) 38

C-doped GaAs base layer (30 nm thick) (2×10²⁰ cm⁻³) 39

Si-doped In_{0.5}Ga_{0.5}P emitter layer (50 nm thick) (1×10¹⁸ cm⁻³) 40

Si-doped GaAs cap layer (100 nm thick) (5×10¹⁸ cm⁻³) 41 step-graded Si-doped InGaAs cap layer (50 nm thick) 42 (with InAs molar ratio changing from 0 to 0.5; from 8×10¹⁸ cm⁻³ to 4×10¹⁹ cm⁻³)

A WSi layer (700 nm thick) is disported on the layer 42. The WSi layer is vertically etched by using a photoresist mask so as to form the emitter electrode 43. The layers 42, 41, and 40 are etched by using the emitter electrode 43 as a mask so that the layer 39 is exposed. Then, an SiO₂ film is formed on the entire wafer surface, and an SiO₂ side wall (wall length=1.0 □m) is formed by anisotropic dry etching, (not shown). The layers 39 and 38 are etched so that the layer 37 is exposed, by using the emitter electrode 43 and the SiO₂ side wall as a mask. Etching is performed to the middle of the substrate 36 so that elements, i.e., devices of InGaP/GaAs HBTs, are isolated. The SiO₂ side wall is then removed. In the course of these steps, a native oxide film 44 (1-5 nm thick) occurs on the exposed surface of the semiconductor layers (or on the top surface of the substrate 36 and the layers 37 and 39, and the end surfaces of the substrate 36 and the layers 37 and 42). The native oxide film 44 is composed of Ga₂O₃, As₂O₃, In₂O₃, and P₂O₅ each of which contains one constituent element (i.e., Ga, As, In, and P) of the semiconductor layers. (See FIG. 3(a))

Then, an Si bond-creating layer 45 (3 nm thick) and an SiN insulating layer 46 (150 nm thick), which functions as a surface protective layer, are sequentially formed on the entire surface by ECR-sputtering. In the course of these steps, the oxide bonding layer 47 (containing such oxide as Ga—O—Si) occurs between the native oxide film 44 and the bond-creating layer 45 by combining oxygen in the former and silicon in the latter. (See FIG. 2(b))

Finally, the base electrode 48 and the collector electrode 49 are formed on the GaAs base layer 39 and the GaAs subcollector layer 37, respectively, by a lift-off technique. In this way, the desired HBT is completed. (See FIG. 3(c))

The strongly bonding structure in this example consists of the native oxide film 44, the oxide bonding layer 47, the Si bond-creating layer 45, and the SiN insulating layer 31. The Si bond-creating layer 45 may disappear from the finished product. As in Example 1, the HBT in this example is characterized in that the SiN insulating layer 46 is formed on the top surface of the substrate 36 and the layers 37 and 39 as well as on the end surface of the substrate 46 and the layers 37 to 42 such that the Si bond-creating layer 45 is inserted thereunder. Therefore, the SiN insulating layer 31 firmly bonds to the semiconductor layers even if it is formed by the ECR-sputtering technique.

The technique in this example may be applied not only to the InP/InGaAs HBT mentioned above but also to InGaP/InGaAs HBP and InP/InGaAs HBT and other HBTs based on III-V compound semiconductors. The HBT may be of pnp type instead of pnp type, and it also may be of collector-top type instead of emitter-top type.

### EXAMPLE 4

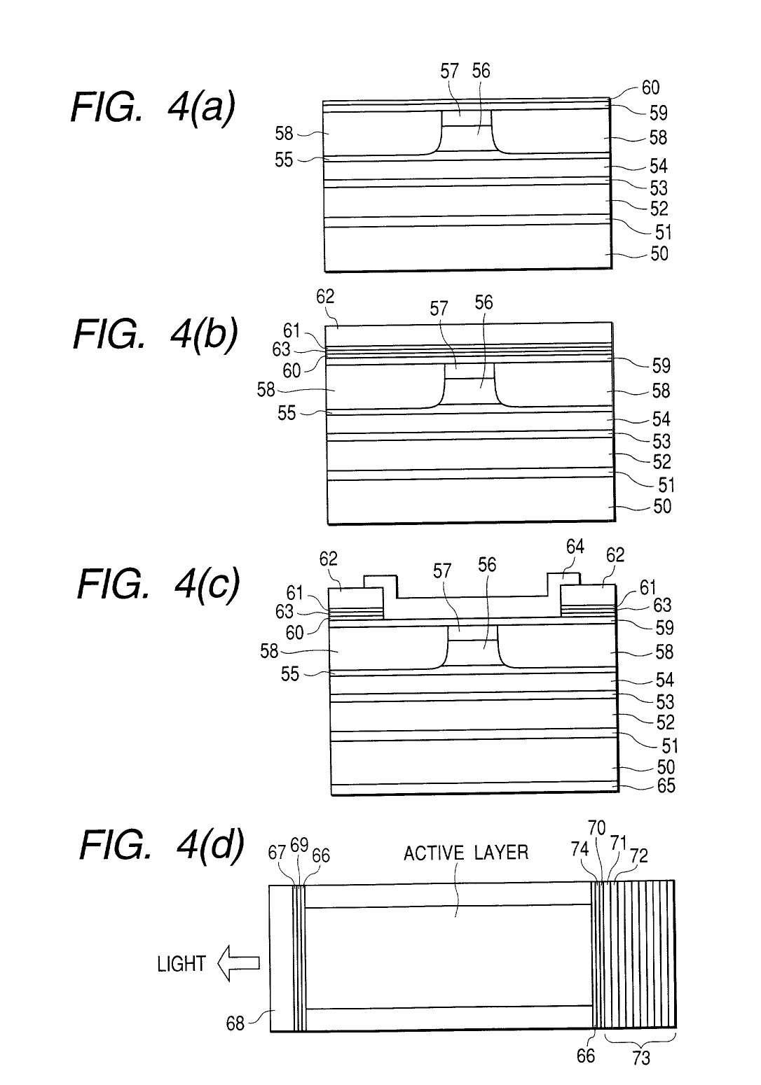

This example demonstrates the production of a semiconductor laser, which is shown in FIGS. 4(a) to 4(c) (sectional views) and FIG. 4(d) (plan view). The production starts with sequential epitaxial growth of various layers (specified below) on an n-GaAs substrate 50.

GaAs buffer layer 51

n-Al_{0.7}Ga_{0.3}InP clad layer 52

pseudomorphic quantum well active layer 53 composed of:

undoped Al_{0.45}Ga_{0.55}InP barrier layer (4 nm thick)

In_{0.6}Ga_{0.4}P pseudomorphic quantum well layer (8 nm thick)

Al_{0.55}Ga_{0.45}InP SCH layer (4 nm thick)

(SCH=separate confinement heterostructure)

p-Al_{0.7}Ga_{0.3}InP clad layer 54

p-InGaP etching-stop layer 55

p-Al_{0.7}Ga_{0.3}InP clad layer 56

p-Al_{0.7}Ga_{0.3}As cap layer 57

The layers 57 and 56 undergo etching through an SiO₂ mask (not shown) so that a ridge consisting of the layers 57 and 56 is formed. An n-GaAs current confinement layer 58 is selectively grown. By removing the SiO₂ mask, a p-GaAs contact layer 59 is formed. In the course of these steps, a native oxide layer 60 (such as Ga₂O₃ and As₂O₃) occurs on the surface of the p-GaAs contact layer 59. (See FIG. 4(a))

Then, an Si bond-creating layer 61 (3 nm thick) and an SiN insulating layer 62 (400 nm thick), which functions as a surface protective layer, are sequentially formed on the entire surface by ECR-sputtering. In the course of these steps, the oxide bonding layer 63 (containing such oxide as Ga—O—Si) occurs between the native oxide film 60 and the bond-creating layer 61 by combining oxygen in the former and silicon in the latter. (See FIG. 4(b))

A p-side ohmic electrode 64 is formed on the GaAs contact layer 59, and an n-side ohmic electrode 65 is formed on the GaAs substrate 50. (See FIG. 4(c))

The layered product undergoes cleavage in the atmosphere. After cleavage, a native oxide film 66 (1-5 nm thick) occurs on the exposed cleavage plane of the substrate 50 and the layers 51 to 59. The native oxide film 66 is composed of Ga₂O₃, As₂O₃, Al₂O₃, In₂O₃, P₂O₅, and the like, which are oxides of the constituent elements Ga, As, Al, In, and P. On the cleavage plane (at emission side), an Al bond-creating layer (3 nm thick) 67 and an AlN insulating layer 68, which has a thickness equivalent to an optical length of λ/4 (λ=oscillating wavelength) and functions as a low reflection film, are formed by ECR-sputtering. On the cleavage plane (at reflection side), an Si bond-creating layer (3 nm thick) 70 and an insulating layer 73, which functions as a high reflection film, are formed by ECR-sputtering. The insulating layer 73 consists of five dual-layers, each of which comprises a SiN layer 71 and a SiO₂ layer 72 placed one over the other. The SiN layer 71 has a thickness equivalent to an optical length of λ/4 (λ=oscillating wavelength). In the course of these steps, the oxide bonding layer 69 (containing such oxide as Ga—O—Al) occurs between the native oxide film 66 (on the cleavage plane at emission side) and the layer 67 by combining oxygen (in the former) and aluminum (in the latter). Also, the oxide bonding layer 74 (containing such oxide as Ga—O—Si) occurs between the native oxide film 66 (on the cleavage plane at the reflection side) and the layer 70 by combining oxygen (in the former) and silicon (in the latter). In this way, the desired semiconductor laser is completed. FIG. 4(d) shows an electrode stripe with an active layer placed underneath.

As mentioned above, the semiconductor laser in this example has three kinds of strongly bonding structures. The first one consists of the native oxide film 60, the oxide bonding layer 63, the Si bond-creating layer 61, and the SiN insulating layer 62. The Si bond-creating layer 61 may disappear from the finished product. The second one consists of the native oxide film 66, the oxide bonding layer 69, the Al bond-creating layer 67, and the AlN insulating layer 69 which functions as the low reflection film. The Al bond-creating layer 67 may disappear from the finished product. The third one consists of the native oxide film 66, the oxide bonding layer 74, the Si bond-creating layer 70, and the insulating layer 73 which functions as the high reflection film. The Si bond-creating layer 70 may disappear from the finished product. For the same reason as explained in Example 1, these strongly bonding structures provide firm bonding between each of the insulating layers 62, 68, and 72 and the respective semiconductor layers.

In this example, the Si bond-creating layer 61 interposed between the p-GaAs contact layer 59 and the SiN insulating layer 62 ensures firm bonding even if the SiN insulating layer 62 is formed by ECR-sputtering.

In addition, the semiconductor laser in this example has the Al bond-creating layer 67 between the cleavage plane and the AlN insulating layer 68, and the Si bond-creating layer 70 between the cleavage plane and the SiN insulating layer 73. The bond-creating layers 67 and 70 ensure firm bonding even if the insulating layers 68 and 73 are formed by ECR-sputtering. This structure also provides well-controlled reflectivity. It is not always necessary to employ all of the three strongly bonding structures mentioned above.

### EXAMPLE 5

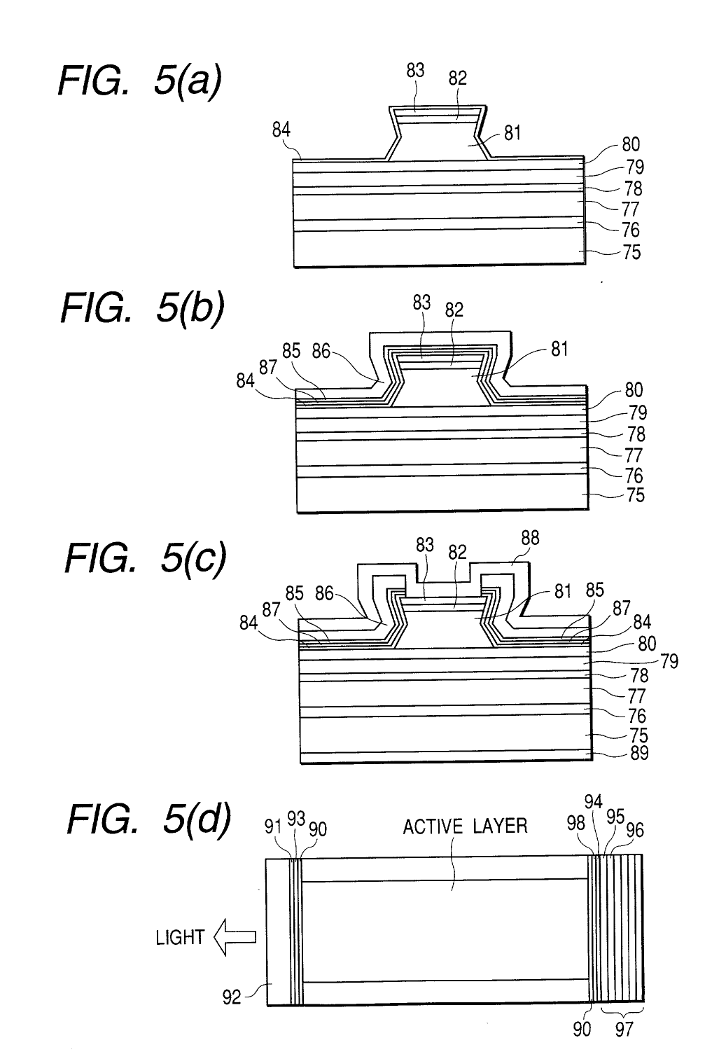

This example demonstrates the production of a semiconductor laser, which is shown in FIGS. See 5(a) to 5(c) (sectional views) and FIG. 5(d) (plan view). The semiconductor laser in this example differs from that in Example 4 in that it has no current confinement layer in Example 4 (as a selectively grown semiconductor layer) rather it utilizes the strongly bonding structure as the current confinement layer.

The production starts with sequential epitaxial growth of various layers (specified below) on an n-GaAs substrate 75.

GaAs buffer layer 76

n-InGaP clad layer 77

pseudomorphic quantum well active layer 78 composed of:

undoped In_{0.18}Ga_{0.82}As_{0.63}P_{0.37} barrier layer (35 nm thick)

In_{0.16}Ga_{0.84}As pseudomorphic quantum well layer (7 nm thick)

p-InGaP clad layer 79

p-GaAs optical waveguide layer 80

p-InGaP clad layer 81

p-GaAs cap layer 82

p-GaAs contact layer 83

The layers 83, 82, and 81 undergo etching through an SiO₂ mask (not shown), so that a ridge is formed. The SiO₂ mask is removed. In the course of these steps, a native oxide layer 84 (1-5 nm thick) occurs on the exposed surface of each semiconductor layer (i.e., the top surface of the layers 80 and 83, and the edge surface of the layers 81 to 83). The native oxide layer is composed of In₂O₃, Ga₂O₃, As₂O₃, P₂O₅, and the like, which are oxides of each of the constituent elements (i.e., In, Ga, As, and P) of the semiconductor layers. (See FIG. 5(a))

Then, an Si bond-creating layer 85 (3 nm thick) and an SiN insulating layer 86 (300 nm thick), which functions as a surface protective layer as well as a current confinement layer, are sequentially formed on the entire surface by ECR-sputtering,. In the course of these steps, the oxide bonding layer 87 (containing such oxide as Ga—O—Si) occurs between the native oxide film 84 and the bond-creating layer 85 by combining oxygen (in the former) and silicon (in the latter). (See FIG. 5(b))

Etching is performed to remove that part of the layers 86, 85, 87, and 84 where the p-side ohmic electrode 88 is formed. The p-side ohmic electrode 88 is formed on the p-GaAs contact layer 59 on the upper surface of the wafer. The n-side ohmic electrode 89 is formed on the lower surface of the n-GaAs substrate 75. (See FIG. 5(c))

The layered product undergoes cleavage in the atmosphere. After cleavage, a native oxide film 90 (1-5 nm thick) occurs on the exposed cleavage plane of the substrate 75 and the layers 76 to 83. The native oxide film 66 is composed of In₂O₃, Ga₂O₃, As₂O₃, P₂O₅, and the like, which are oxides of each of the constituent elements In, Ga, As, and P. On the cleavage plane (at emission side), an Al bond-creating layer (3 nm thick) 91 and an AlN insulating layer 92, which has a thickness equivalent to an optical length of λ/4 (λ=oscillating wavelength) and functions as a low reflection film, are formed by ECR-sputtering. On the cleavage plane (at reflection side), an Si bond-creating layer (3 nm thick) 94 and an insulating layer 97 which functions as a high reflection film, are formed by ECR-sputtering. The insulating layer 97 consists of three each of SiO₂ layer 95 and hydrogenated amorphous silicon (a-Si:H) layer 96 which are placed one over the other. The SiO₂ layer 95 has a thickness equivalent to an optical length of λ/4 (λ=oscillating wavelength). In the course of these steps, the oxide bonding layer 93 (containing such oxide as Ga—O—Al) occurs between the native oxide film 90 (on the cleavage plane at emission side) and the layer 91 by combining oxygen (in the former) and aluminum (in the latter). Also the oxide bonding layer 98 (containing such oxide as Ga—O—Si) occurs between the native oxide film 90 and the bond-creating layer 94. In this way, the desired semiconductor laser is completed. (See FIG. 5(d))

As mentioned above, the semiconductor laser in this example has three kinds of strongly bonding structures. The first one consists of the native oxide film 84, the oxide bonding layer 87, the Si bond-creating layer 85, and the SiN insulating layer 86 (which functions as the surface protective film as well as the current confinement layer). The Si bond-creating layer 85 may disappear from the finished product. The second one consists of the native oxide film 90, the oxide bonding layer 93, the Al bond-creating layer 91, and the AlN insulating layer 92 (which functions as the low reflection film). The Al bond-creating layer 91 may disappear from the finished product. The third one consists of the native oxide film 90, the oxide bonding layer 98, the Si bond-creating layer 94, and the insulating layer 97 (which functions as the high reflection film). The Si bond-creating layer 94 may disappear from the finished product. For the same reason as explained in Example 1, these strongly bonding structures provide firm bonding between each of the insulating layers 86, 92, and 97 and each of the respective semiconductor layers.

In this example, the Si bond-creating layer 85 is interposed between the SiN insulating layer 86, the top surface and side surface of the ridge (consisting of the layers 81 and 83), and the surface of the layer 80 surrounding the ridge. This Si bond-creating layer 85 ensures good bonding to the semiconductor even if the SiN insulating layer 86 is formed by ECR-sputtering. In addition, the semiconductor laser in this example has the Al bond-creating layer 91 between the cleavage plane ,and the AlN insulating layer 92 and the Si bond-creating layer 94 between the cleavage plane and the SiN insulating layer 97. These bond-creating layers 91 and 94 ensure firm bonding even if the insulating layers 92 and 97 are formed by ECR-sputtering. This structure also provides well-controlled reflectivity. It is not always necessary to employ all of the three strongly bonding structures mentioned above.

### EXAMPLE 6

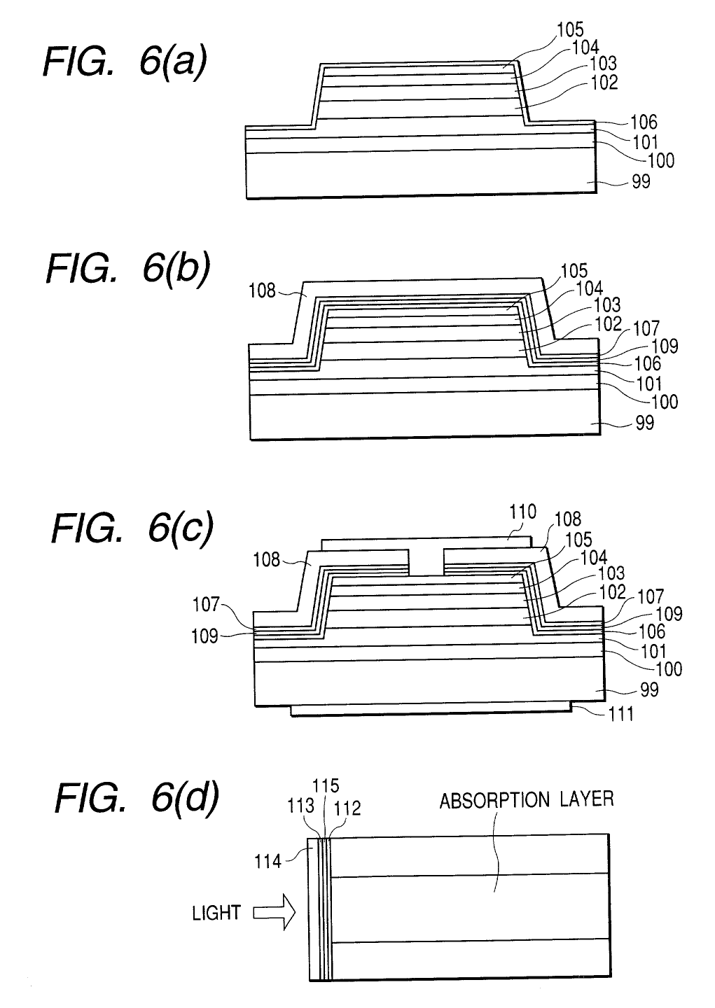

This example demonstrates the production of a photodiode, which is shown in FIGS. 6(a) to 4(c) (sectional views) and FIG. 6(d) (plan view). The production starts with sequential epitaxial growth of various layers (specified below) on a p-InP substrate 99.

p-In_{0.52}Al_{0.19}Ga_{0.29}As buffer layer (700 nm thick) 100

a first p-In_{0.52}Al_{0.19}Ga_{0.29}As core layer (2000 nm thick) 101

undoped In_{0.53}Ga_{0.47}As light-absorbing layer (2000 nm thick) 102

a second n-In_{0.52}Al_{0.19}Ga_{0.29}As core layer (2000 nm thick) 103

n-InAlAs buffer layer (1000 nm thick) 104

n-In0.53Ga0.47As contact layer (700 nm thick) 105

For mesa isolation, the layers 105 to 102 are removed by etching through an SiO₂ mask (not shown). The SiO₂ mask is removed. In the course of these steps, a native oxide layer 106 (1-5 nm thick) occurs on the exposed surface of each semiconductor layer (i.e., the top surface of the layers 101 and 105, and the respective edge surface of each of the layers 102 to 105. The native oxide layer is composed of In₂O₃, Al₂O₃, Ga₂O₃, As₂O₃, P₂O₅, and the like, which are oxides of each of the constituent elements (i.e., In, Al, Ga, As, and P) of the semiconductor layers. (See FIG. 6(a))

Then, an Si bond-creating layer 107 (3 nm thick) and an SiN insulating layer 108 (300 nm thick), which functions as a surface protective layer, are sequentially formed on the entire surface by ECR-sputtering. In the course of these steps, the oxide bonding layer 109 (containing such oxide as Ga—O—Si) occurs between the native oxide film 106 and the bond-creating layer 107 by combination of oxygen (in the former) and silicon (in the latter). (See FIG. 6(b))

Etching is performed to remove that part of the layer where the p-side ohmic electrode is formed. The p-side ohmic electrode 110 and the n-side ohmic electrode 111 are formed respectively on the n-In_{0.53}Ga_{0.47}A contact layer 105 and the p-InP substrate 99. (See FIG. 6(c))

The layered product undergoes cleavage in the atmosphere. After cleavage, a native oxide film 112 (1-5 nm thick) occurs on the exposed cleavage plane of the substrate 99 and the layers 100 to 105. The native oxide film 112 is composed of In₂O₃, Al₂O₃, Ga₂O₃, As₂O₃, P₂O₅, and the like, which are oxides of each of the constituent elements In, Al, Ga, As, and P. On the cleavage plane (at light-receiving side), an Si bond-creating layer 113 (2 nm thick) an SiN insulating layer 114, which has a thickness equivalent to an optical length of λ/4 (λ=oscillating wavelength), and functions as an anti-reflection film, are formed by ECR-sputtering. In the course of these steps, the oxide bonding layer 115 (containing such oxide as Ga—O-—Si) occurs between the native oxide film 112 and the bond-creating layer 113 by combining oxygen (in the former) and silicon (in the latter). In this way, the desired photodiode is completed. (See FIG. 6(d))

As mentioned above, the photodiode in this example has two kinds of strongly bonding structures. The first one consists of the native oxide film 106, the oxide bonding layer 109, the Si bond-creating layer 107, and the SiN insulating layer 86 which functions as the surface protective film. The Si bond-creating layer 107 may disappear from the finished product. The second one consists of the native oxide film 112, the oxide bonding layer 115, the Si bond-creating layer 113, and the surface protective layer 114 which functions as the anti-reflection film. The Si bond-creating layer 113 may disappear from the finished product. For the same reason as explained in Example 1, these strongly bonding structures provide firm bonding between each of the insulating layers 108 and 114 and each of the respective semiconductor layers.

In this example, the Si bond-creating layer 107 is interposed between the SiN insulating layer 108 and the top surface and side surface of the mesa (consisting of the layers 1010 to 105). This Si bond-creating layer 107 ensures good bonding to the semiconductor even if the SiN insulating layer 108 is formed by ECR-sputtering. In addition, the photodiode in this example has the Si bond-creating layer 113 between the end surface of the photodiode and the SiN insulating layer 114. This bond-creating layer 113 ensures firm bonding to the semiconductor even if the SiN insulating layer 108 is formed by ECR-sputtering. This structure also provides well-controlled reflectivity and end-reflecting structure with high bond strength. It is not always necessary to employ all of the two strongly bonding structures mentioned above.

In one embodiment of the semiconductor device of the invention, the insulating layer is an end high-reflecting film of a semiconductor laser. “High reflectivity” means a higher reflectivity than the facet reflectivity. The exact facet reflectivity depends on the effective refractive index of the facet, which depends on the optical oscillation wavelength; nevertheless, a typical facet reflectivity of some infra-red laser diodes is about 28-30%. In many commercially available laser diodes, at least one facet is covered with a “high reflecting film”, the reflectivity of which ranges between 70-95%. The reflectivity of the “high reflecting film” is determined by the specific characteristics of each kind of laser diodes. For example, the invention uses a high reflective coating (ex. reflectivity of 40%) to enhance the reflection better than the facet reflection.

In another embodiment of the semiconductor device of the invention, the insulating layer comprises at least one of an end anti-reflecting film and an end low reflecting film of a photodiode. “Anti-reflectivity” means a minimum or zero reflectivity. “Low reflectivity” means less reflectivity than the facet reflectivity. Reflectivity depends on the reflecting film thickness. The reflectivity becomes minimum when the optical length (i.e., the thickness multiplied by the refractive index of the reflecting film) of the reflecting film is a quarter of the light wavelength if the reflecting film consists of a single layer. The minimum value depends on the wavelength and on the refractive index of the film and the semiconductor.

### EXAMPLE 7

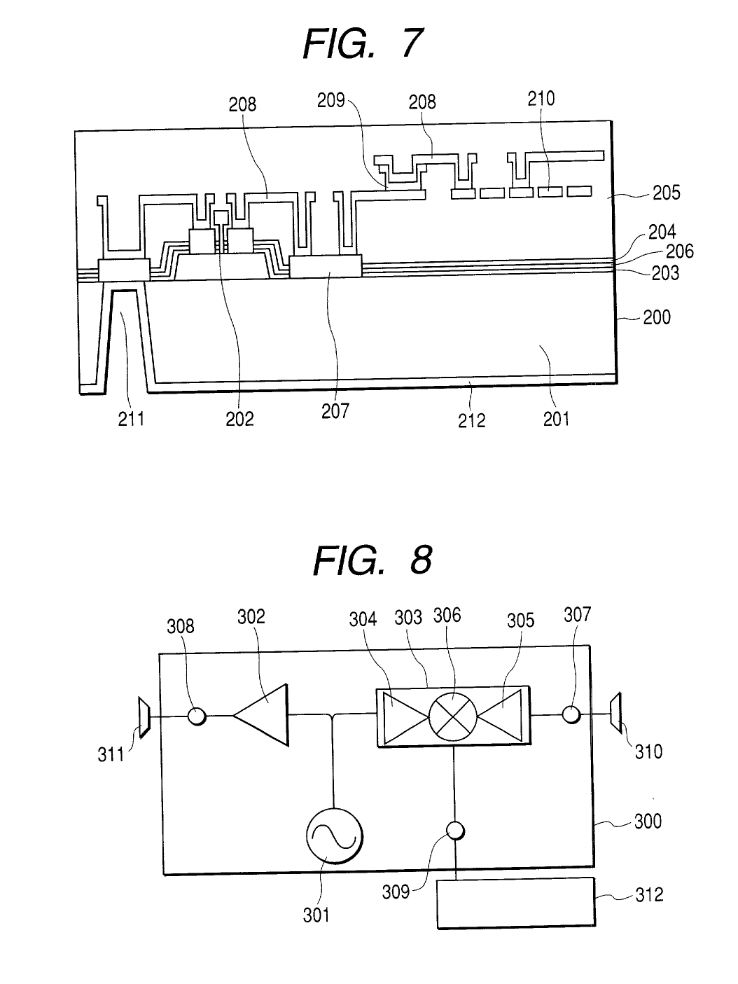

This example demonstrates a monolithic microwave integrated circuit (MMIC) of microstrip type 200 as shown in FIG. 7 (sectional view). This MMIC consists of a GaAs substrate 201 and those microwave circuit elements formed thereon which include a metamorphic HEMT 202, a resistance 207, capacitance 209 (including a conductor 208 of waveguide as an electrode), an inductance 210, and a conductor 208 of waveguide. On the reverse side of the substrate, a via hole 211 and a grounding conductor 212 are formed. The metamorphic HEMT 202 is the one shown in Example 1. The strongly bonding structure of the present invention is used to improve the bond between the semiconductor substrate 201 and the interlayer insulating film 205 (which is an SiO₂ insulating layer). This object is achieved by sequentially forming the Si bond-creating layer 204 and the interlayer insulating film 205 on the native oxide film 203 which occurs on the GaAs semiconductor substrate 201 when the mesa of the metamorphic HEMP is formed. In this way, the oxide bonding layer 206 occurs between the native oxide film 203 and the Si bond-creating layer 204. The MMIC according to this example has high reliability because the surface protective film or interlayer insulating film of the metamorphic HEMT has increased bond strength.

### EXAMPLE 8

This example demonstrates an on-vehicle radar as shown in FIG. 8. The radar consists of a high-frequency module 300 (including a voltage-variable oscillator 301, an amplifier 302, a receiver 303, a receiving antenna terminal 307, a transmitting antenna terminal 308, and a terminal 309), a receiving antenna 310 connected to the receiving antenna terminal 307, a transmitting antenna 311 connected to the transmitting antenna terminal 308, and a signal processing system connected to the terminal 309. The MMIC in Example 7 is used in the voltage-variable oscillator 301, the amplifier 302, and the receiver 303 in FIG. 8.

The on-vehicle radar functions in the following manner. The voltage-variable oscillator 301 generates 76-GHz signals. The signals are amplified by the amplifier 302 and then radiated from the transmitting antenna 311 through the transmitting antenna terminal 308. The signals reflected and returned by an object are received by the receiving antenna 310. The received signals pass through the receiving antenna terminal 307 and enters the receiver 303 in which they are amplified by the amplifier 305. The amplified signals are mixed with reference signals (76 GHz) by the mixer 306 in the receiver 303. (The reference signals are generated by the voltage-variable oscillator 301 and amplified by the amplifier 304 in the receiver 303.) This mixing provides IF (intermediate frequency) signals. The IF signals pass through the terminal 309 and enter the signal processing system 312 which calculates the relative velocity, distance, and angle of the object.

The on-vehicle radar in this example has high reliability because it employs the MMIC in Example 7 as the high-frequency module.

### EXAMPLE 9

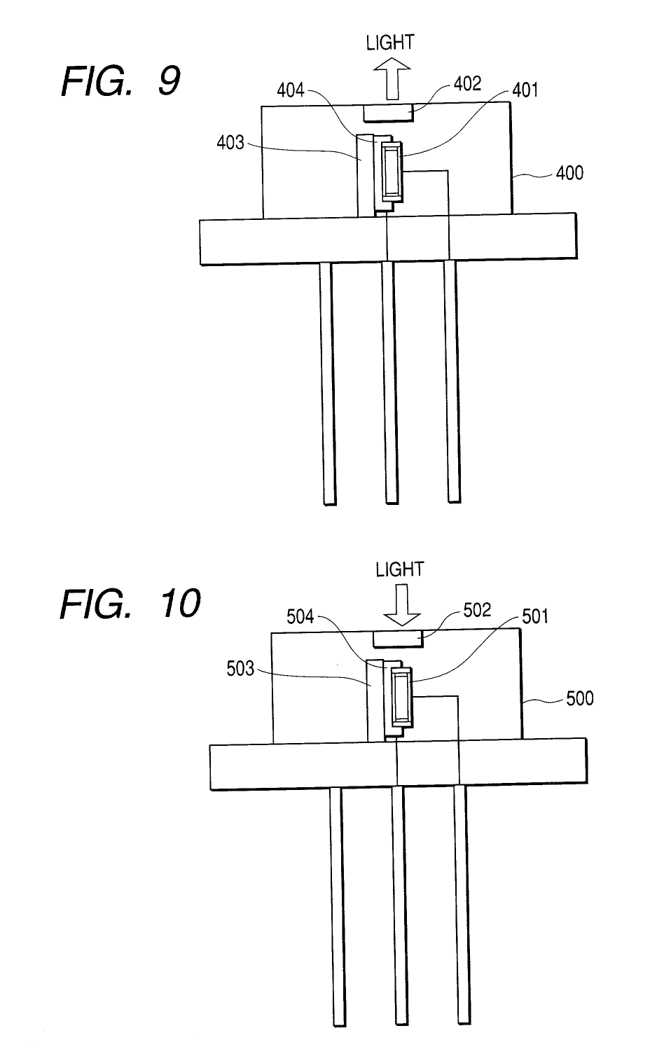

This example demonstrates a semiconductor laser device which is shielded by resin molding as shown in FIG. 9 (sectional view). A semiconductor laser element 401 is bonded to an SiC submount 403 with an AuSn solder 404. The assembly is entirely shielded by resin mold 400. The upper electrode and the lower electrode (through AuSn solder 404) of the semiconductor laser element 401 are wired to their respective shielded terminals. The emitted light radiates through the window 402.

In the prior art, shield by resin molding is inexpensive but poor in airtightness. Therefore, the traditional semiconductor laser shielded by resin molding has the disadvantage that the insulating layer therein is easy to peel. However, the semi-conductor laser 401 of this invention does not have this disadvantage, and hence it prevents yields from decreasing due to peeling.

### EXAMPLE 10

This example demonstrates a photodiode device which is shielded by resin molding as shown in FIG. 10 (a sectional view). A photodiode element 501 is bonded to a SiC submount 503 with an AuSn solder 404. The assembly is entirely shielded by a resin mold 500. The upper electrode and the lower electrode (through AuSn solder 504) of the photodiode element 501 are wired to their respective shielded terminals. The received light enters the photodiode 501 through the window 502.

In the prior art, shield by resin molding is inexpensive but poor in airtightness. Therefore, the traditional photodiode shielded by resin molding has the disadvantage that the insulating layer therein is easy to peel. However, the photodiode 501 of this invention does not have this problem, and it prevents yields from decreasing due to peeling.

The present invention provides an insulating layer with a high bonding strength regardless of the methods by which the insulating film is formed on the surface of semiconductor.

The foregoing invention has been described in terms of preferred embodiments. However, those skilled, in the art will recognize that many variations of such embodiments exist. Such variations are intended to be within the scope of the present invention and the appended claims.

What is claimed is:

1. A semiconductor device having a semiconductor, an insulating layer, and a bonding structure formed therebetween, the bonding structure comprising:
an oxide layer having a constituent element of said semiconductor;
an oxide bonding layer; and
a bond-creating layer,
wherein said oxide bonding layer being formed by reacting oxygen in said oxide layer with a constituent element of said bond-creating layer, and
said bond-creating layer containing the constituent element that oxidizes with the oxygen in said oxide layer and a second constituent element that reacts with a constituent element of said insulating layer.

2. The semiconductor device as defined in claim 1, wherein said bond-creating layer is a silicon layer.

3. The semiconductor device as defined in claim 1, wherein said insulating layer is a silicon nitride layer.

4. The semiconductor device as defined in claim 1, wherein the bond-creating layer is an intermediate which is eliminated from the strongly bonding structure when the strongly bonding structure is finished.

5. The semiconductor device as defined in claim 1, wherein said insulating layer is a surface protective film of at least one of a field effect transistor, a bipolar transistor, a semiconductor laser, and a photodiode.

6. A semiconductor device as defined in claim 1, wherein said insulating layer is an end high-reflecting film of a semiconductor laser.

7. A semiconductor device as defined in claim 1, wherein said insulating layer comprises at least one of an end anti-reflecting film and an end low reflecting film of a photodiode.

8. A semiconductor device as defined in claim 1, wherein said insulating layer is an interlayer insulating film of a microwave integrated circuit.

9. A high-frequency module comprises a transmitting antenna terminal, a receiving antenna terminal, a terminal for intermediating frequency signals from a mixer in a receiver, and a semiconductor device as defined in claim 1,
wherein said semiconductor comprises a voltage-variable oscillator, an amplifier placed between said voltage-variable oscillator and said transmitting antenna terminal, the receiver placed between said voltage-variable oscillator and said receiving antenna terminal, and
the semiconductor is insulated by said insulating layer as an interlayer insulating film which is bound to the semiconductor by the bonding structure formed therebetween.

10. A high-frequency module as defined in claim 9 is used as an on-vehicle radar, further comprises a receiving antenna connected to said receiving antenna terminal, a transmitting antenna connected to said transmitting antenna terminal, and a signal processing system connected to said terminal.

11. A semiconductor device as defined in claim 5, wherein said semiconductor laser is shielded by resin molding.

12. A semiconductor device as defined in claim 6, wherein said semiconductor laser is shielded by resin molding.

13. A semiconductor device as defined in claim 5, wherein said photodiode is shielded by resin molding.

14. A semiconductor device as defined in claim 7, wherein said photodiode is shielded by resin molding.

15. A method for producing a semiconductor device having a semiconductor, an insulating layer, and a bonding structure formed therebetween, comprising:
providing on top of the semiconductor an oxide layer having a constituent element of the semiconductor;
providing on top of the oxide layer a bond-creating layer;
forming an oxide bonding layer between the oxide layer and the bond-creating layer by reacting oxygen in the oxide layer with a constituent element of the bond-creating layer;
providing on top of the bond-creating layer an insulating layer by reacting a constituent element of the bond-creating layer with a constituent element of said insulating layer.

16. A method for producing a semiconductor device as defined in claim 15, whereby said insulating layer is provided by plasma CVD or plasma sputtering.

17. An apparatus for producing a semiconductor device having a semiconductor, an insulating layer, and a bonding structure formed therebetween, comprising:
means for providing on top of the semiconductor an oxide layer having a constituent element of the semiconductor;
means for providing on top of the oxide layer a bond-creating layer;
means for forming an oxide bonding layer between the oxide layer and the bond-creating layer by reacting oxygen in the oxide layer with a constituent element of the bond-creating layer;
means for providing on top of the bond-creating layer an insulating layer by reacting a constituent element of the bond-creating layer with a constituent element of said insulating layer.

18. A computer program product for producing a semiconductor device having a semiconductor, an insulating layer, and a bonding structure formed therebetween, comprising:
a module for providing on top of the semiconductor an oxide layer having a constituent element of the semiconductor;
a module for providing on top of the oxide layer a bond-creating layer;
a module for forming an oxide bonding layer between the oxide layer and the bond-creating layer by reacting oxygen in the oxide layer with a constituent element of the bond-creating layer;
a module for providing on top of the bond-creating layer an insulating layer by reacting a constituent element of the bond-creating layer with a constituent element of said insulating layer.
